(19) United States
(12) Patent Application Publication
(10) Pub. No.: US 2007/0177415 A1
(43) Pub. Date: Aug. 2, 2007

(54) High performance mass storage systems

(76) Inventor: Jeng-Jye Shau, Palo Alto, CA (US)

Correspondence Address: JENG-JYE SHAU, 991 AMARILLO AVE., PALO ALTO, CA, 94303, US

(21) Appl. No.: 10/642,861

(22) Filed: Jul. 18, 2003

Related U.S. Application Data
(60) Provisional application No. 60/404,736, filed on Aug. 20, 2002.

(51) Int. Cl. G11C 15/02

(52) U.S. Cl. 365/50

(57) ABSTRACT

A data access system for accessing data stored in a first and a second memory devices. The first and second memory devices have a difference of latency ΔL that constitutes a time-duration by which the first memory device starts an initial data access earlier than in the second memory device. A data access controller is implemented to simultaneously access data in the first and second memory devices and to stop accessing data in the first memory device once a data access operation has begun in the second memory device. Therefore, the first memory device stored data only accessed initially in a time duration corresponding substantially to the difference of latency ΔL before the data access operations is started in the second memory device.

This Application claims a Priority Filing Date of Aug. 20, 2002 benefited from a previously filed Application 60/404,736 filed by the same inventor of this Application.

### FIELD OF THE INVENTION

The present invention relates to data storage systems, and more particularly to methods for improving the system performance of mass data storage systems.

### BACKGROUND OF THE INVENTION

FIG. 1(a) is the system block diagram for a typical computer data storage system. When the computer is not active, raw data are stored in nonvolatile storage devices such as hard disks (HD), compact disks (CD), or magnetic tapes (MT). These mass storage units (MSU) can store large amount of data at low cost. However, they are slower than integrated circuit (IC) memory devices such as dynamic random access memory (DRAM) or static random access memory (SRAM). The computer does not process the raw data in MSU directly. Software programs with properly formatted instruction and data structure must be loaded into the main memory to be processed by the computer. The storage devices used for the main memory are typically DRAM. It is also a common practice to reserve a block of memory space in a hard disk as the “swapping memory”: When the total capacity of the main memory is not large enough to store all the activated executable software programs, the swapping memory is used to store part of the executable software that is not currently processed by the computer. A current art computer can execute billions of operations per second. The DRAM device used for main memory is not fast enough to provide data at such a high transfer rate. It is therefore necessary to have multiple levels of memory devices as shown in FIG. 1(a). The execution unit (EU) in the computer operates on registers. When the needed data are not in the registers, the execution units check on the first level (L1) cache for the data. The L1 cache is usually a high-speed memory device embedded on the same integrated circuit (IC) as the execution unit. Sometimes, there is more than one level of such embedded cache devices in the execution unit. When the needed data is not found in L1 cache (called “cache miss”), the system looks for the data in the second level (L2) cache. The L2 cache is usually a synchronized SRAM device that has larger capacity than L1 cache, but operates at lower speed. If the needed data is found in L2 cache (called “cache hit”), the data is send to the registers for execution and to the L1 cache (called “cache update”). In this way, the next time when the execution unit wants the same data, there will be a cache hit at L1 cache. L2 cache is usually on the same circuit board but not in the same IC as the execution unit. Sometimes, there are more than one level of such on board cache devices. For example, we can have level 2 and level 3 (L3) caches on board. For the case when the needed data are not found in those cache devices, the system will look for the data in the main memory. When the needed data are found in main memory (called “page hit” in current art), the data is sent to the execution unit for processing, and to caches for cache updates. If the data are not found in the main memory (called “page miss”), the system will look for the data in the swapping memory. The needed data in the swapping memory will be placed into the main memory to replace a least used memory block, while the replaced main memory block will be swapped back into the swapping memory space. We can consider the DRAM devices as a type of cache for the slower hard disk swapping memory.

In general, current art data storage systems store large data in low-cost high-capacity storage devices, while using smaller high-performance memory devices to store copies of recently used data. For most of operations, recently used data are likely to be used again and again (called “principle of locality” in current art). It is therefore likely to find the data in the high performance memory devices. In this way, we can enjoy the high performance of high cost devices most of time, while lower the system cost by store most data in low cost devices. FIG. 1(b) shows the flowchart of such hierarchical data storage system. When an execution unit need data, it looks into the fastest and closest memory device first. If the data are found (hit), the memory access operation is finished. If the data are not found (miss), the system looks into the next level. The same procedures are repeated until the data are found in a lower level memory device. Then the data are sent to the execution unit, while high level memory devices with cache misses are updated.

The data storage system described in FIGS. 1(a,b) are simplified for clearness. The operation of hierarchical memory system is actually very complex. Special cares need to be taken to assure coherence and efficiency of the system. Details such as the size of each level of memory device and the methods on how to update those devices are controlled by sophisticated control mechanisms. A wide variety of methods have been developed to improve the efficiency of various memory devices for different applications. In order to describe the basic principles of the present invention, we will not cover those complex details. The readers are assumed to know the complexity of current art system so that we can use the simplified system in FIGS. 1(a,b) as a comparison to data storage systems of the present invention.

Current art hierarchical memory system works very well when the execution units are looping around a small memory block. However, it is not designed to handle the situation when a large memory block is required. For example, assume that 512K bytes of data are accessed repeatedly in a system that has a 256K byte L2 cache. While we are accessing the first 256K of the data, the whole L2 cache will be updated with those data. When we are reading the second 256K bytes of the data block, we will get cache miss every time, and the L2 cache will be filled with the second 256K of the data block. When we are going back to access the first 256K, we will get cache misses all the time. The procedures repeats on and on. The net result is that L2 cache is completely useless under this situation. In this case the L2 cache actually slow down the data access procedure due to the overhead needed to lookup and to update the L2 cache. One obvious solution for the above problem is to have a 512K L2 cache, but that doubles the cost, and that does not solve the problem when we need to access a bigger data block. Even if we use a cache large enough to store the whole data block, the system performance is still degraded. When the cache is mostly occupied by one block of data, we will have cache misses while other data are needed. This type of problem is called “memory overload” problem in the following discussion. One solution for the problem is to separate those large data blocks. That is why graphic controller usually has its own memory device reserved for graphic display only. The most common solution for the memory overload problem used by current art system is to declare those large data blocks not cacheable. The system will, bypass the L2 cache to access the data. This solution sacrifices the performance for large data access, but it saves the cache capacity for smaller accesses. The same problem exists in every level of the hierarchical data storage system. The so called “large data block” is a relative concept. At high level caches a relatively small data block is enough to cause the above problems. If we declare any data block that can cause the problem at any level as not cacheable, the whole cache system won't be very useful. One current art solution is to declare data blocks “not cacheable” at different levels; one data block can be cacheable at lower level memory devices, while it is not cacheable at higher level devices. This and other current art solutions minimized the damages of the memory overload problem for current art system, but they do not actually solve the problem. These “solutions” also create complexity in control mechanism. It is therefor highly desirable to find a true solution to the data overload problem, and to simplify the control mechanisms.

Another commonly experienced memory overload problem happens on main memory. If a program tries to access a memory block larger than the size of the main memory, the program will spend most of time swapping data between the hard disk and the main memory, and the program will run extremely slow. There is no elegant solution for a current data storage system to solve this main memory overload problem. The difficulty comes from the fact that hard disk (HD) data access time is about one million times slower than typical IC devices. FIG. 1(c) is a simplified diagram describing the structure of a hard disk (HD) unit. Each HD unit comprises a few rotational magnetic disks (131). Data are read from or written into those magnetic disks by magnetic heads (133). There is one head for each side of each magnetic disk. All the heads moves with identical movements. The data storage areas on the disk are divided into traces and sections. A trace (135) is a circular line centered on the rotation axes of the disk, while a section (137) is a pie shaped area as shown in FIG. 1(c). A cylinder is a combination of all the traces on all the magnetic disks that have the same distance to the rotation axes. To access data in the HD unit, we must move the magnetic heads (133) to the target cylinder, and wait until the target section rotate under the magnetic head. In current art HD terminology, the time spent to move the magnetic heads to the target cylinder is called “seek time”, and the time spent to wait for the target section is called “latency time”. Seek time and latency time is not fixed number. Seek time is proportional to the distance the magnetic head need to move in order to find the right cylinder. The latency time is proportional to the distance the target section needs to rotate to the magnetic heads. The average seek time for current art HD unit is typically 5-10 milliseconds, while the average latency time is within about the same range. The total access time to access the first set of data is seek time plus latency time. Typical access time for current art IC memory is around 1-10 nanoseconds. The access time for HD unit is about one million times slower than IC devices. Once the target section is found, the HD unit can access data at reasonable performance. Current art HD unit data access rate is between a few million to a few billion bits per second, which is slower but comparable to IC data transfer rate.

HD devices are always by far slower than IC storage devices, especially in access time. The hard disk industry has been constantly improving the density and data transfer rate of HD devices, but there is little progress in improving the access time. Due to mechanical nature of the seek mechanism, it is very difficult to improve seek time by changing the HD devices. Current art HD often use DRAM as cache device to improve performance. The DRAM cache store recently used data. If the data needed by a new access are found in the DRAM, the data access speed can be as fast as DRAM access speed. However, most of hard disk activities need to access large amount of data. Using a small DRAM cache will have little advantage, while using a big DRAM cache will increase cost dramatically. Current art DRAM cache for HD is therefore found to be ineffective. The only current art solution to solve the memory overload problem in swapping memory is to increase the size of the main memory. That is the reason why high end work station, which runs very large programs, typically use extremely large main memory. This solution is very expensive. It is therefore highly desirable to provide a cost efficient solution for this swapping problem.

The operation principle of optical compact disk (CD) is very similar to that of HD. An optical head is moved to access data on the CD using similar mechanism as HD. Current art CD is slower than HD. The seek time for CD is typically more than 100 milliseconds, while its latency time is about the same as HD. Typically, the data transfer rate for CD is also much slower than HD. CD units are originally read only storage device. Currently, CD writers are available at reasonable price. The data rate for CD write or re-write operation is about 2-4 times slower than that of read operation. In general, the performance of CD is worse than HD, but CD has significant cost advantage. CD has another advantage that its disk can be replaced easier, and the cost of the disk is significantly lower than HD disks. Both HD and CD are by far slower than IC storage devices. That often becomes the bottleneck for current art data storage systems. It is strongly desirable to provide methods to improve the performance of HD and CD data storage systems.

### SUMMARY OF THE INVENTION

The primary objective of this invention is, therefore, to provide practical methods to improve performance of data storage systems. The other objective is to reduce the cost of data storage systems. Another objective is to provide solutions for the memory overload problem. It is also a major objective of the present invention to provide efficient methods to improve the performance of HD and CD data storage systems. These and other objectives are accomplished by novel methods in the data storage control mechanisms.

While the novel features of the invention are set forth with particularly in the appended claims, the invention, both as to organization and content, will be better understood and appreciated, along with other objects and features thereof, from the following detailed descriptions taken in conjunction with the drawings.

### BRIEF DESCRIPTION OF THE DRAWINGS

FIG. 1(a) is the block diagram for a prior art data storage system;

FIG. 1(b) is a flowchart for data access procedures for the system in FIG. 1(a);

FIG. 1(c) is a simplified diagram for the structure of a hard disk device;

FIG. 2(a) illustrates the timing signals for current art SRAM;

FIG. 2(b) illustrates the timing signals for current art DRAM;

FIG. 2(c) describes the data access procedures for an DRAM/SRAM memory system of the present invention;

FIG. 3(a) shows an example of circuit block diagram for a slow memory supported by a fast memory device;

FIG. 3(b) describes the access procedures of a memory system of the present invention;

FIG. 4(a) shows a method to balance data transfer rate using parallel processing;

FIG. 4(b) is the circuit block diagram for another method used to balance data transfer rates between two different buses;

FIG. 4(c) is the timing signals for the system in FIG. 4(b);

FIG. 4(d) shows a method to combine the methods in FIGS. 4(a, b);

FIG. 4(e) shows the timing signals for the system in FIG. 4(d);

FIG. 5(a) shows the procedures for data replacement access time reduction method;

FIG. 5(b) illustrates the procedures for data prefetch method;

FIG. 5(c) shows the procedures for the sequential prediction mechanism;

FIG. 5(d) shows the procedures for predicted data prefetch mechanism;

FIG. 6(a) is a block diagram for a mass storage system of the present invention;

FIG. 6(b) shows the data distribution methods for the system in FIG. 6(a);

FIG. 6(c) describes the procedure to use hard disk device to reduce the effect of compact disk access time; and

FIG. 7 is an overview for a data storage system of the present invention.

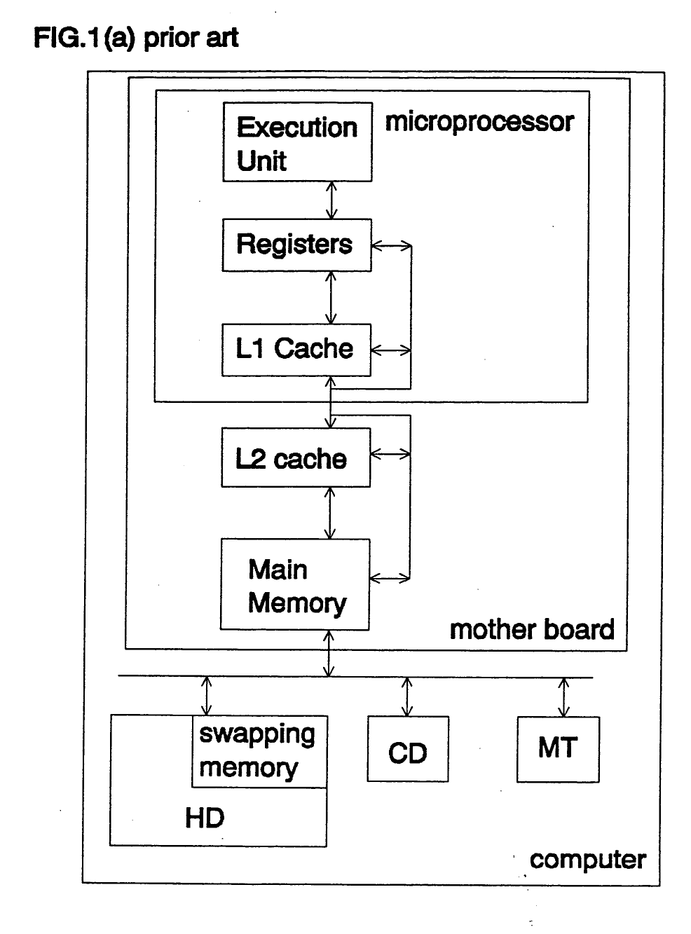

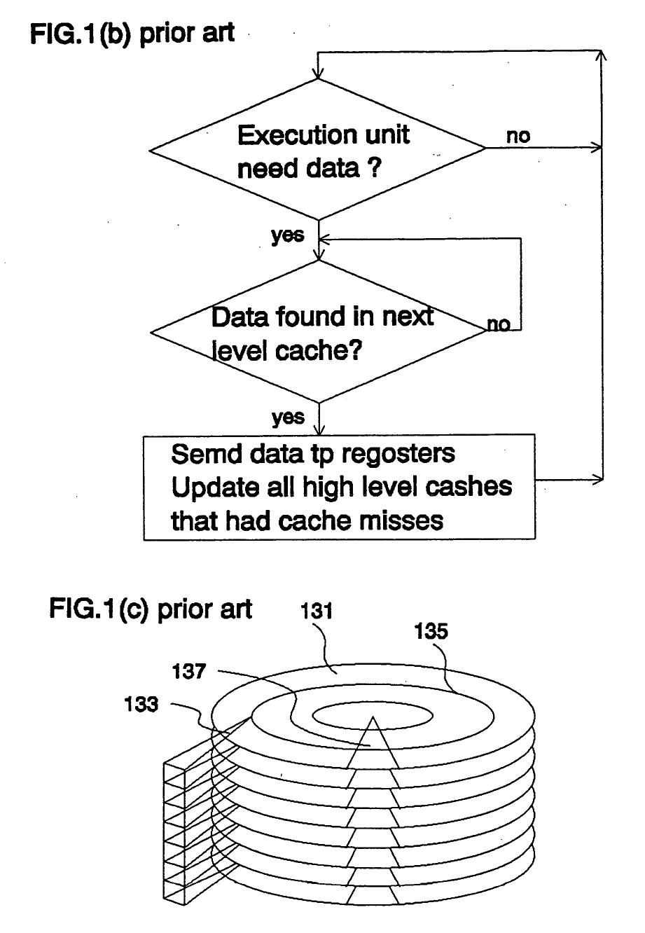

### DETAILED DESCRIPTION OF THE INVENTION

Prior art data storage systems assume that DRAM is slower than SRAM, and hard disk is slower than DRAM. Based on these assumptions, a small SRAM is used as the cache for larger DRAM, and a smaller DRAM is used to store recently used data for a larger hard disk. Relying on the principle of locality, such hierarchical data storage system can achieve reasonable performance at reasonable cost. On the other hand, current art system is highly inefficient in accessing large data blocks due to the memory overload problem discussed in background sections. In addition, current art cache memories are not optimized for burst mode memory devices. The relationship between L2 cache and main memory is used as an example to illustrate the inefficiency of current art cache.

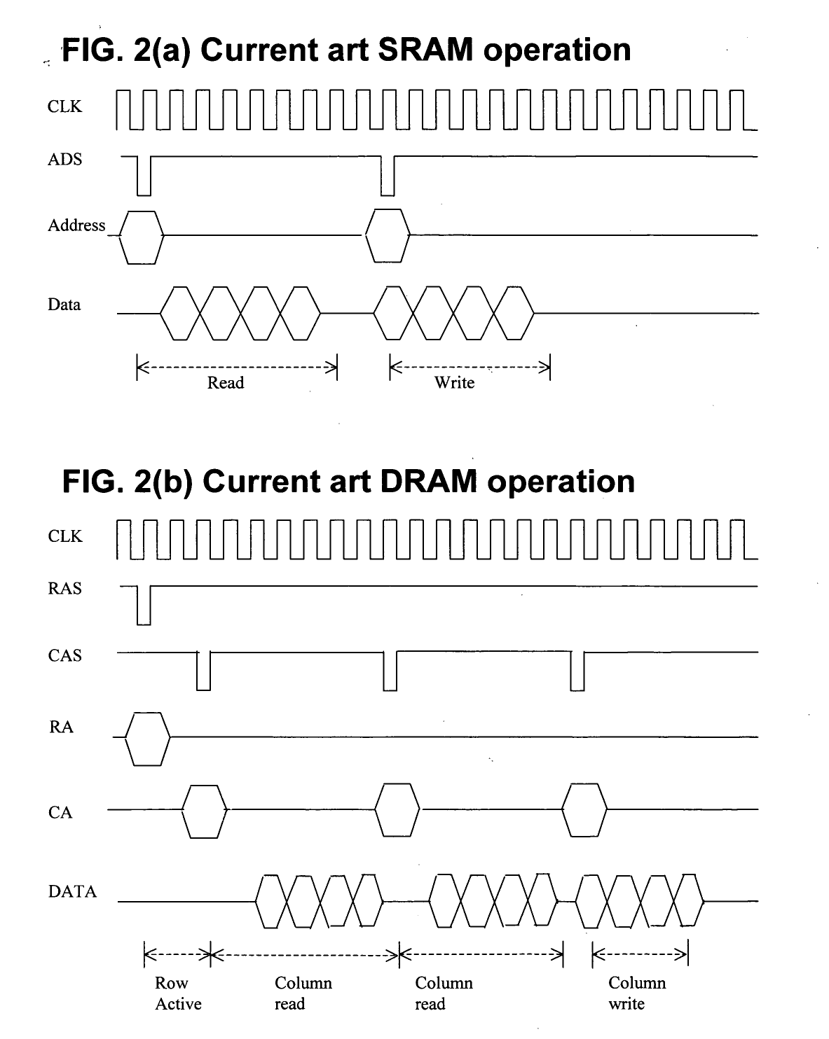

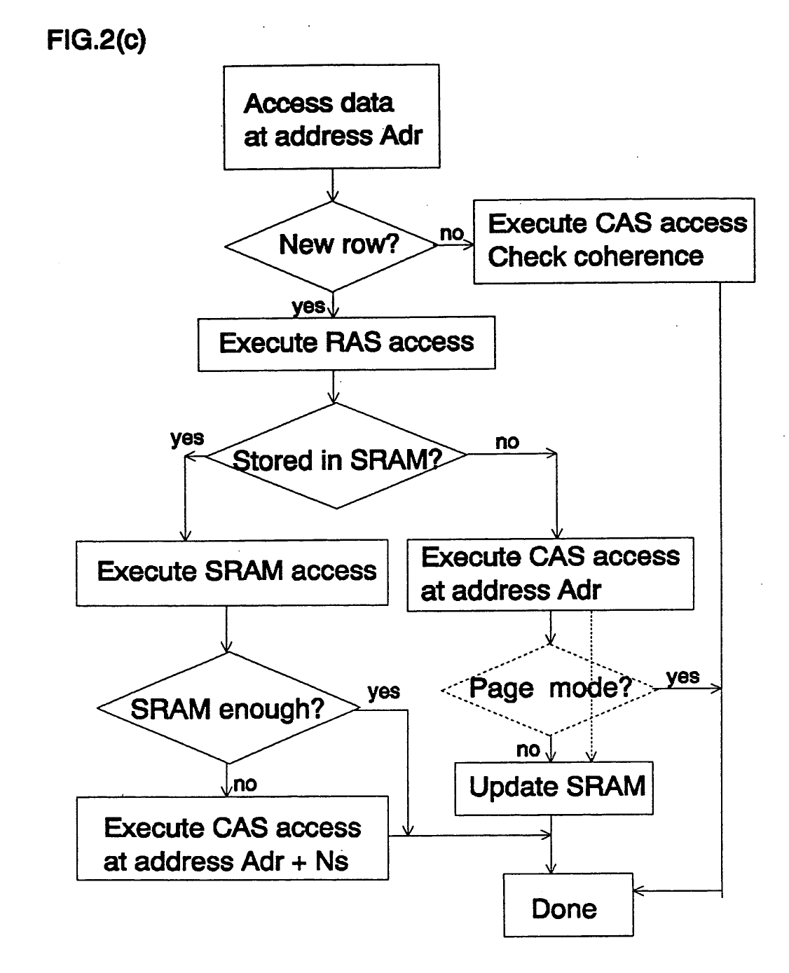

FIGS. 2(a,b) compare the memory operation between SRAM and DRAM. For an SRAM memory read operation, typically the first data set (201) will be ready 2 clocks after the address strobe (ADS) indicating address is ready as shown in FIG. 2(a). On the other words, the read access time of the SRAM device in this example is two clocks. After the first data set, we can read one set of data for every clock. For a SRAM memory write operation, one set of data can be written into the memory for every clock after the address strobe (ADS) as shown in FIG. 2(a). For a typical DRAM device, each set of address is divided into two subsets—row address (RA) and column address (CA). To access data in a new row, the row address is sent to the DRAM signaled by a row address strobe (RAS) as shown in FIG. 2(b). We need to wait for at least two clocks (for a DRAM with row access time 2 clocks) before we can send the column address to the DRAM signaled by column address strobe (CAS). For a DRAM read operation, the first set of data will be ready two clocks after CAS. After the first data set, DRAM can output one set of data for every clock. To access another block of data at a different column address but at the same row address, we do not need to repeat the RAS operation; simply send another CAS, and a new set of data will be ready in 2 clocks following the same procedures. For a DRAM memory write operation, one set of data can be written into the memory for every clock after CADS.

The timing specification of different commercial memory devices may not be exactly the same as the examples shown in FIGS. 2(a,b). For example, many DRAM devices have column or row access time at 3 clocks instead of 2 clocks; many SRAM devices also need 3 clocks instead of 2 clocks. For another example, double data rate (DDR) devices are able to access two sets of data per clock after the first data set. However, it is generally true that the speed difference between SRAM and DRAM is significant only for accessing the first set of data in a new DRAM row. SRAM has little or no speed advantage for column accesses or burst accesses. The reason is simple. After a row address strobe (RAS), data stored in the whole row of a DRAM device are placed into a memory buffer. For each following CAS, part of the data in the memory buffer is placed into an input/output (I/O) buffer. This procedure is very similar to the procedure of SRAM operation. The speed of CAS access is therefore similar to the speed of an SRAM access. In the following clocks, the operation is between the I/O buffer and the memory bus. The speed of this buffer-to-bus procedure is usually limited by bus properties instead of memory device properties. Therefore, both SRAM and DRAM should have similar burst mode data transfer rate. Although DRAM as a memory device is indeed slower than most SRAM devices, this speed difference only influences the timing for row access.

Prior art caches assume that SRAM is always faster than DRAM, and they are designed to have maximum hit rate. Whenever there is a cache miss, prior art caches always copy the data from DRAM to SRAM so that next time the data will be found in SRAM; the only exception is when the data is declared “non-cacheable”.

A memory system of the present invention recognizes the fact that DRAM is actually as fast as SRAM most of time; the only exception is new row access. Therefore, SRAM is only used for new row accesses. FIG. 2(c) is the flowchart for this novel memory system. For each new memory access at address Adr, the memory controller checks high order address bits (higher than DRAM column address bits) to see if it is accessing a new row. If it is not a new row memory access, a CAS operation is directly sent to DRAM. The SRAM device may need to execute snoop operation for coherence consideration in the same way as prior art cache. If it is a new row memory access, an SRAM lookup is started, and a RAS operation is started in DRAM in parallel. If a copy of the data is found in the SRAM (hit), a burst mode data access is executed in SRAM following the same procedures as prior cache operation. If all the data requested by this memory access can be provided by SRAM, there will be no CAS operation sent to DRAM. If the memory access requests more data than then burst mode SRAM can provide (for example, an page mode access), CAS operation starting at address (Adr+Ns) is sent to DRAM. Where Ns is the number of data provided by SRAM. After SRAM finishes its operation, DRAM will take over the following operations. If the requested data set is not found in the SRAM (miss), CAS operation starting at Adr is sent to DRAM. The next step is to store a copy of data starting form Adr to (Adr+Ns−1) into SRAM following the same update procedures as prior art cache device. There are two possible options to handle this update procedure. The first option, indicated by the dashed arrow line in FIG. 2(c), is to execute the update as soon as the data block is declared cacheable. The second option, indicated by dashed question block, is to avoid SRAM update for a DRAM page mode access. A page mode operation accesses thousands of data sets in burst mode. The performance loss due to this option is negligible, while this option provides a complete solution to the memory overload problem.

The memory system in FIG. 2(c) has the following advantages over prior art cache. First of all, the novel memory system provides effective solution for the memory overload problem. When the system is accessing a large data block, only (Ns/Nrow) of the data is stored into SRAM, where Nrow is the number of data set in a DRAM row. For example, if Nrow is 4000 while Ns is 4, only 1/1000 of data will occupy the SRAM. On the other words, the data block need to be 1000 times larger then the size of SRAM in order to cause memory overload problem. In case that we use the second update option to avoid cache update for page mode access, the memory overload problem will be completely solved no matter how large the target data block is, if the large data block access is executed by page mode. The second advantage is that we can use a small SRAM to achieve the same performance as a prior art cache memory using a much large SRAM. Based on the principle of locality, CAS accesses are likely to group together. Therefor the chance to have CAS access is by far more than the chance to have RAS access. In addition, the first data access to the same row is likely to happen at the same starting address due to the nature of computer program. Therefore, the chance for RAS access is close to (Ns/Nrow). Therefor, memory systems of the present invention require much smaller SRAM to achieve the same performance. For a new row access hit or a column access, the performance of the memory system of the present invention is identical to that of prior art cache hit. If the SRAM size for both systems are the same, the hit rate of the system of the present invention will be better. Data storage systems of the present invention always has better performance/cost efficiency because we do not waist unnecessary SRAM space to store data that will not improve system performance.

While specific embodiments of the invention have been illustrated and described herein, it is realized that other modifications and changes will occur to those skilled in the art. It should be understood that the above particular SRAM/DRAM example is for demonstration only and is not intended as limitation on the present invention. The same principle can be applied to on-chip caches or any other level in the memory hierarchy. Detailed operation procedures also may vary for different situations.

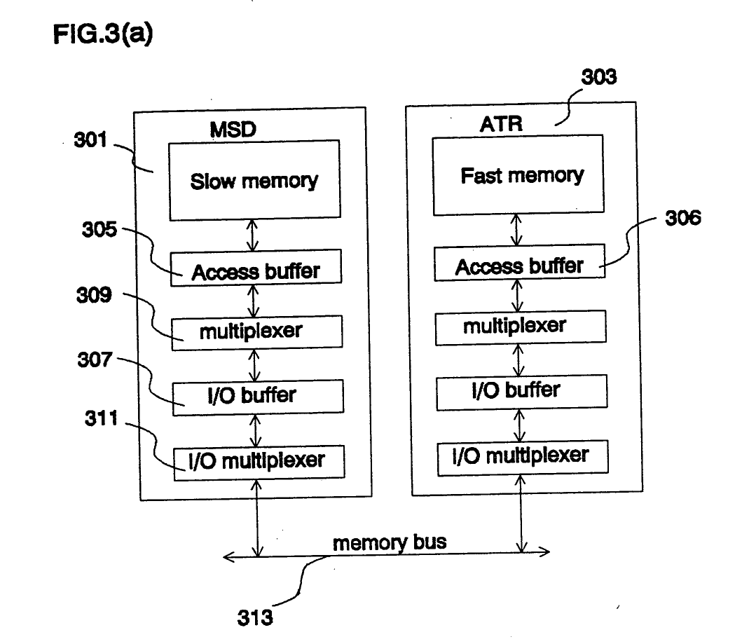

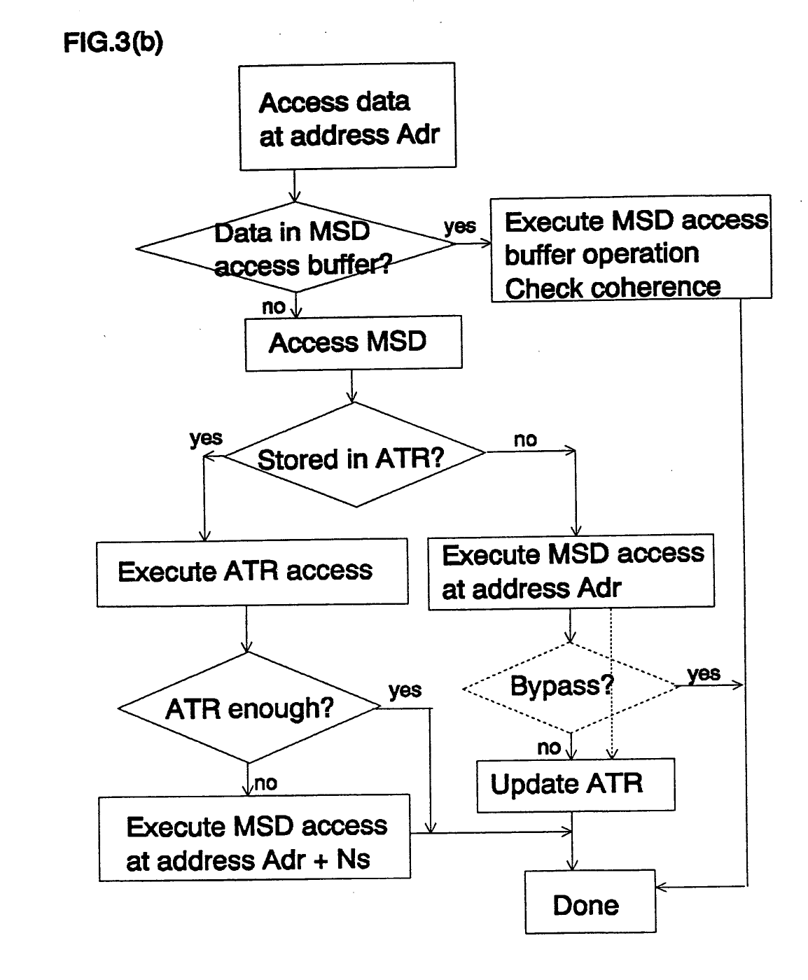

For a generalized case, we have a slow memory device (301) supported by a fast memory device (303) as shown in FIG. 3(a). For each slow memory access, the number of data accessed by the slow memory is N_{L}, and the access time in T_{L}. For each memory access operation, all the data accessed by one memory operation (called “access unit”) are stored in an internal buffer called access buffer (305). The access buffer (305) can have more than one or many entries to store the results of one or multiple memory accesses. Part of the data in the access buffer are placed into an I/O buffer (307) through a multiplexer (309). The procedure to move data from the access buffer to I/O buffer is called “access buffer operation”. The data in the I/O buffer (309) are placed into data bus (313) through an I/O multiplexer (311) during burst mode operations. The procedure to move data from the I/O buffer to bus is called “I/O operation”. For each fast memory access, the number of data accessed by the fast memory is N_{f}, and the access time in T_{f}. The fast memory also has its own access buffer (306) and similar I/O path. Since the size of fast memory is typically smaller, we usually have N_{L}>N_{f}, and T_{L}>T_{f}. The speed for access buffer operations and for I/O operations should be similar for both devices (301, 303). Ideally, the above memory system is equivalent to a memory device that has the access time of the fast memory (303) and the capacity of the slow memory (301). The function of the fast memory is to shorten the memory access time for the slower memory. The fast memory (303) is therefor called “access time reducer (ATR)”, and the slow memory (301) is called “main storage device (MSD)” in the present invention. Using the SRAM/DRAM system described in previous sections as example, SRAM is used as the ATR for DRAM, while DRAM is used as the MSD. N_{L} is the number of data per DRAM row, and N_{f} is the number of data access for each SRAM operation. Note that DRAM CAS accesses are not considered as DRAM memory accesses because the actual DRAM read/write operations only happen during RAS accesses. DRAM CAS accesses are considered as access buffer operations according to the above definitions. The burst mode data output operations for both DRAM and SRAM are I/O operations according to the above definitions.

FIG. 3(b) is the flowchart for the memory system in FIG. 3(a). For each new memory access at address Adr, the memory controller checks high order address bits to see if the data is already in the MSD access buffer (305). If the data are found in the MSD access buffer (305), an access buffer operation is directly sent to MSD, bypassing ATR. The ATR does not involve data transfer activities under this situation, but it may need to execute coherence update activities similar to current art cache memory. If the data are not found in MSD access buffer, an ATR lookup is started, and an MSD memory access operation is started in parallel. If a copy of the data is found in the ATR (hit), an ATR I/O burst mode operation is executed. If all the data requested by this memory access can be provided by ATR, there will be no access buffer operation to MSD. If the memory access requests more data than the data provided by ATR I/O operations, access buffer operations starting at address (Adr+N_{f}) are started in MSD. After ATR finishes its operation, MSD will take over the following operations. If the requested data set is not found in the ATR (miss), access buffer operations at starting address Adr are executed in MSD. The next step is to update a copy of data starting form Adr to (Adr+N_{f}−1) following the same procedures as prior art cache device. There are two possible options to handle this update procedure. The first option, indicated by the dashed arrow line in FIG. 2(c), is to execute the update as soon as the data block is declared cacheable. The second option, indicated by dashed question block, is to avoid ATR for certain types of data accesses such as page mode operation accessing thousands of data sets in burst mode. The performance loss due to this option is negligible if the number of data accessed is large, while this option provides a complete solution to the memory overload problem. The system described in FIGS. 3(a,b) is called ATR storage system (ATRSS). For an ATRSS system the (N_{L}/N_{f}) ratio, called “access size ratio (ASR)”, is very important. Usually a system with larger ASR will have better performance/cost ratio (PCR). The relationship between T_{L} and T_{f} is also very important. Ideally, we want to have T_{L}=T_{f}+T_{fio}, where T_{fio} is the time to execute a complete ATR I/O operation. When T_{L}=T_{f}+T_{fio}, during an ATR hit there will be no idle time for the MSD to take over data transfer operation from ATR. ASR is a function of T_{L} and T_{f}, so that the optimum value of ASR is constrain by timing requirement. Similar to prior art cache memory system, ATRSS also can have multiple hierarchy levels. For example, we can use a register file as the ATR of a small embedded memory, which is actually an ATR of a larger embedded memory, which serves as the ATR of an external memory, . . . etc. It is also possible to mix ARTSS with conventional cache in a hierarchical storage system. For each hardware system, there is always an optimum ATRSS available. The performance/cost efficiency of ATRSS is typically by far better than that of prior art systems.

In many ways, an ATR can be considered as a special kind of cache memory. The ATR control logic used to support memory coherence and memory update is similar to that of conventional cache. The difference between ATR and prior art cache is that an ATR is used only for accesses that require slow memory accesses. Since there is no point to use a cache when we are accessing the data that have been processed by previous slow memory access, an ATR does not support those operations. Therefore, we can use a small fast memory to achieve better performance than prior art cache memory.

This invention discloses a data access system for accessing data stored in a first and second memory devices. The first and second memory devices have a difference of latency ΔL that constitutes a time-duration by which the first memory device starts an initial data access earlier than in the second memory device. A data access controller is implemented to simultaneously access data in the first and second memory devices and to stop accessing data in the first memory device once a data access operation has begun in the second memory device. Therefore, the first memory device stored data only accessed initially in a time duration corresponding substantially to the difference of latency ΔL before the data access operations is started in the second memory device. In a preferred embodiment, the first and second memory devices have substantially a same continuous data access rate after the initial data accesses in the first and second memory devices are completed. In another preferred embodiment, the second memory device comprises a dynamic random access memory (DRAM) and the first memory device comprising a static random access memory (SRAM). In another preferred embodiment, the DRAM comprising a plurality of rows and the SRAM storing first several data of a plurality of rows in the DRAM and the DRAM storing data of a plurality of entire rows in the DRAM.

This invention further discloses a data memory system that includes a dynamic random access memory (DRAM) and a static random access memory (SRAM) wherein the DRAM includes a plurality of rows and the SRAM storing first several data of a plurality of rows in the DRAM and the DRAM storing data of a plurality of entire rows in the DRAM. In a preferred embodiment, the system further includes a data access means simultaneously accessing data in the DRAM and the SRAM for stopping a data access from the SRAM when an initial data access in the DRAM begins. In another preferred embodiment, the data memory system further includes a data access means for checking data access instructions for sending the data access instructions directly to the DRAM when a data access is for a data stored in a same row compared to a previous data access instruction. In another preferred embodiment, the memory system further includes a data access means for checking data access instructions for sending the data access instructions to the SRAM and DRAM when a data access is for a data stored in a different row compared to a previous data access instruction. In another preferred embodiment, the SRAM storing first several data of a plurality of rows in the DRAM for accessing data from the SRAM during a DRAM latency period. And, the DRAM stores data of a plurality of entire rows in the DRAM for accessing data from the DRAM immediately after the DRAM latency period.

This invention further discloses a method for accessing data stored in a first and a second memory devices having a difference of latency ΔL constituting a time-duration by which the first memory device starts an initial data access earlier than in the second memory device. The method includes a step of simultaneously accessing data in the first and second memory devices and stopping accessing data in second first memory device once an initial data access in the second memory device begins. In a preferred embodiment, the method further includes a step of configuring the first and second memory devices having substantially a same continuous data access rate after the initial data accesses in the first and second memory devices are completed. In another preferred embodiment, the step of accessing data from the second memory device is a step of accessing data from a dynamic random access memory (DRAM) and the step of access data from the first memory is a step of accessing data from a static random access memory (SRAM). In a different embodiment, the step of access data from the DRAM comprising a step of dividing the DRAM into a plurality of rows and storing a plurality of entire rows of data in the DRAM and storing in the SRAM first several data of a plurality of rows as that stored into the DRAM.

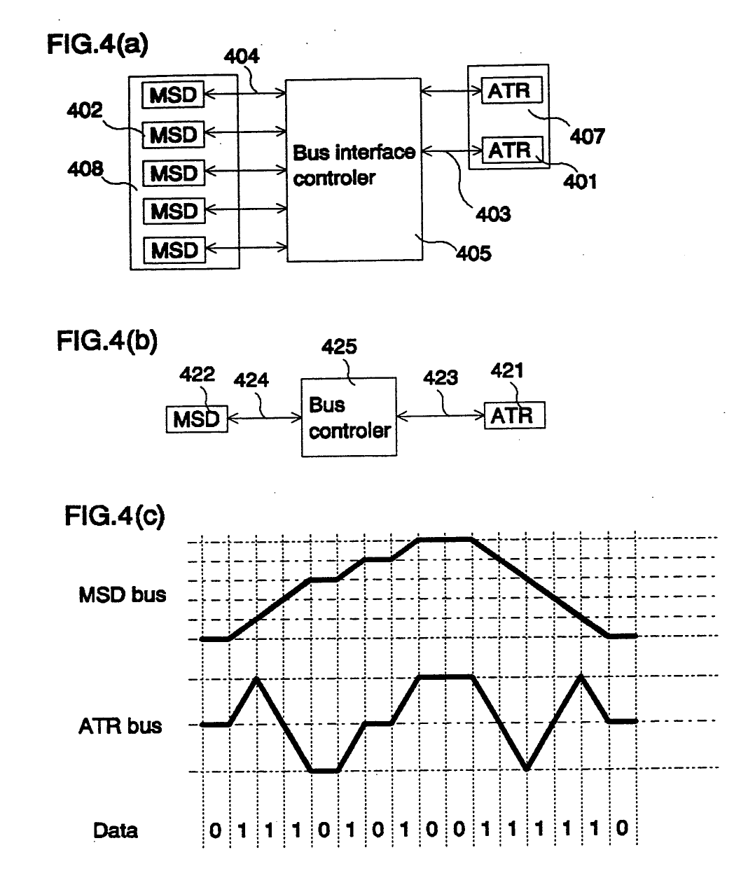

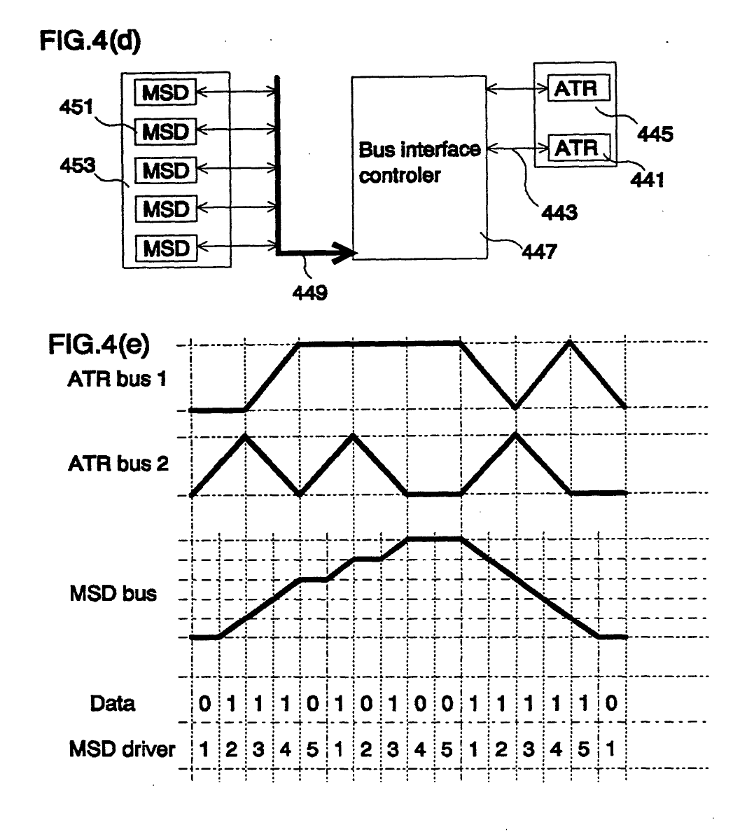

One assumption made in the above discussion is that the speed of I/O operation is the same for both ATR and MSD. This assumption is usually true when both of them are on the same IC or on the same circuit board. However, if ATR is an embedded memory while MSD is an external memory, the I/O operations for the latter are usually slower. This assumption is not a necessary condition. An ATRSS can operate when the I/O operations for ATR and MSD are different. However, it is desirable to have similar data transfer rate between them. One obvious solution is to mix ATRSS with conventional cache in the memory hierarchy. For example, use ATRSS for chip level memories and board level memories, while configure the chip level ATRSS as a conventional cache of the board level ATRSS. Another possibility is to use parallel processing as shown in the example in FIG. 4(a). Assume the speed of MSD bus is M/N times of the speed of ATR bus, where M and N are small integers. In this example, M=2 and N=5. There are 2 ATR's (401) using 2 ATR (403) buses, and there are 5 MSD's (402) using 5 MSD buses (404). These ATR and MSD buses are connection to a bus interface controller (405). The function of this bus interface controller (405) is to distribute data between ATR buses (403) and MSD buses (404) so that they appear to have equivalent total data rate. Those individual buses do not need to have equal transfer rates; each bus can have its own data transfer rate. As soon as the combined data rate of the ATR buses is equivalent to that of the MSD buses, we can treat all the ATR device as one pseudo ATR device (407), and all the MSD devices as one pseudo MSD device (408). The problem for the system in FIG. 4(a) is the additional cost needed to implement the complex bus structure. The cost of the bus interface controller is usually not the problem because logic circuit is cheap. The major cost problem for the system in FIG. 4(a) is that it will require a large number of data buses. FIG. 4(b) shows another data transfer method designed to solve the bus speed difference problem. In this example, ATR devices (421) are connected to an ATR bus (423), while MSD devices (422) are connected to an MDS bus (424). The width of the ATR bus is the same as the width of the MSD bus. Both buses are connected to a bus interface controller (425). Assume that ATR bus bandwidth is N/M times of MSD bus bandwidth, where N and M are small integers. In this particular example, we assume N=5 and M=2. We need to have the same data transfer rate between those two buses of different bandwidth. The method is to transfer data at an amplitude 1/N of the full scale amplitude in MSD bus, and at 1/M of the full scale amplitude in ATR bus. Examples of the data transfer signals are shown in FIG. 4(c). Binary data ‘1’ is represented by change in amplitude, while binary data ‘0’ is represented by no change. In this example, each amplitude change in the MSD bus is limited to ⅕ of full scale, while each amplitude change in the ATR bus is limited to ½ of full scale. In this way, the signals carry identical data with identical transfer rate while meeting the bandwidth limits of both buses. The function of the bus interface controller (425) is to convert data in both buses into proper format. This method is called “amplitude division data transfer rate adjustment (ADDTRA)” method in the present invention. Amplitude division data transfer method has been used for communication devices such as ethernet networking devices. The contribution of the present invention is to use the amplitude division signal format for balancing the data transfer rate between different buses. The limitation of ADDTRA method is that N and M must be small integers. Dividing the amplitude into too many levels will cause noise problem. For complex cases, we can combine ADDTRA method in FIG. 4(b) with parallel bus method in FIG. 4(a) to achieve the purpose. One example for the combined bus structure is shown in FIG. 4(d). In this example, two ATR devices (441) connected to two separated ATR buses (443) to form a pseudo ATR (445). Those two ATR buses are connected to a bus interface controller (447) that is connected to one MSD bus (449). For the case that the ATR bus bandwidth is 2.5 times of that of MSD bus, the data signals in those three buses are shown in FIG. 4(e). The signal in MSD bus still need to use signal division method, while there is no need to do signal division in the ATR buses. We also can place multiple devices on one bus, and transfer data by time sharing. In this example, 5 MSD devices (451) are connected to one MSD bus (449). The data on the MSD bus is divided into packages of 5 data sets. The first MSD device provides the first data set in each package; the second MSD device provides the second data set in each package, . . . etc. This time sharing method allow each individual device operates at lower internal frequencies. Similar time sharing method also can be applied on ATR buses.

The above ATRSS architecture works very well among IC memory devices. The same principles are applicable to mass storage unit (MSU) such as hard disk, compact disk, or magnetic tapes, but additional performance improve methods are required to make MSU ATR devices meaningful. MSU devices are extremely slow comparing to IC memory devices. The average seek time for current art HD unit is typically 5-10 milliseconds, while the average latency time is in the same range. The total access time to access the first set of data is seek time plus latency time. Typical access time for current art IC memory is around 1-10 nanoseconds. The access time for HD is therefor about one million times slower than IC devices. Current art HD data access rate is between a few million to a few billion bits per second, which is slower but comparable to IC data transfer rate. Current art HD often use DRAM as cache device to improve performance. The DRAM cache store recently used data. If the data needed by a new access are found in the DRAM, the data access speed can be as fast as DRAM access speed. However, most of hard disk activities need to access large amount of data. Using a small DRAM cache will have little advantage, while using a big DRAM cache will increase cost dramatically. Current art DRAM cache for HD is always found to be ineffective.

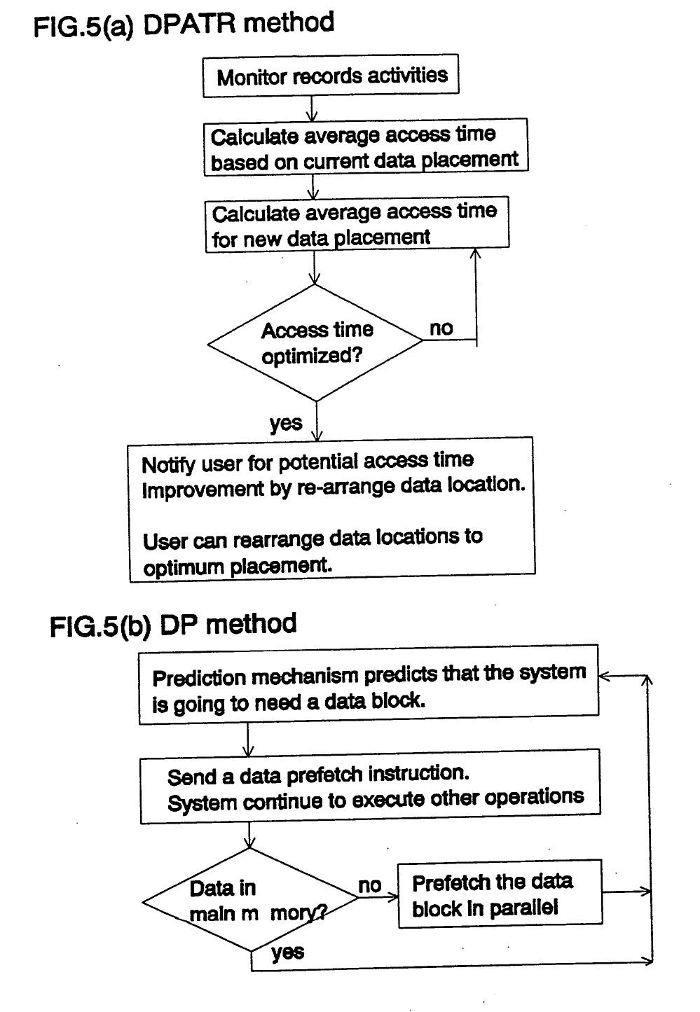

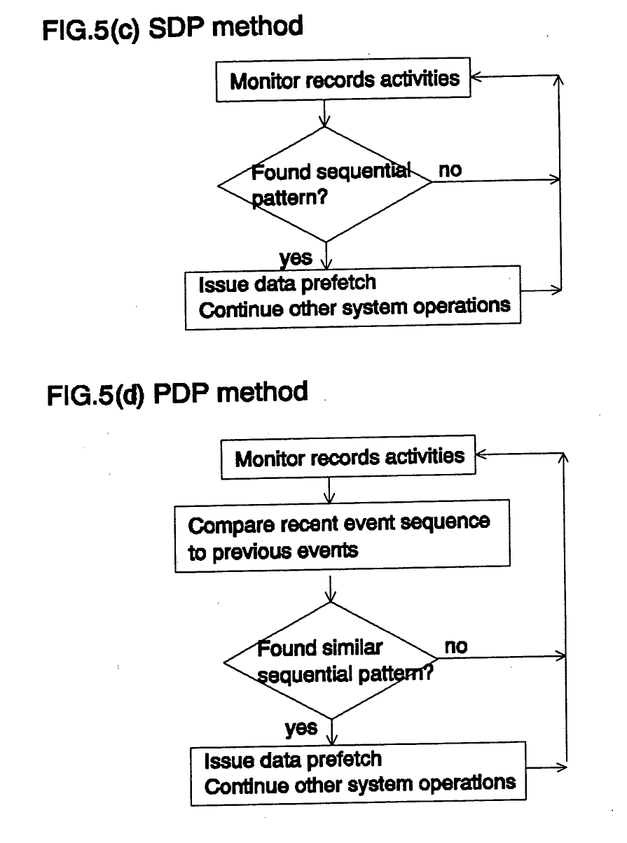

The present invention provides data access control methods to reduce the influence of HD access time. The first method is called “data placement access time reduction (DPATR)”. The average seek time for an HD or CD is proportional to the average distance of head movement. Data accesses are not completely random. Only a small fraction of files are frequently accessed, and they are accessed in similar sequence most of time. The average access time is therefore strongly dependent on the placement of data files. FIG. 5(a) shows the flowchart for DPATR method of the present invention. A HD monitor records hard disk activities. Whenever there is a hard disk operation, the monitor records the address of the operations. These addresses can be translated into cylinder and section locations in the hard disk. Based on these data, the seek time between each two events can be calculated. We also can calculate the average seek time if the files location are re-arranged. It is therefore possible to find the best placement based on recent hard disk events. Frequently used files should be placed closed to each other. The file tend to follow another file should be placed after the file on the same cylinder. The optimization mechanism is very similar to the methods used by place-and-route tools for IC design. There are many possible ways to find the optimum placement; details of the mechanism are not covered in the present specification. When a significant improvement can be achieved, the user is notified for such advantage. The user can then execute a procedure to re-arrange the data in the hard disk to achieve optimum access time for future operations. Another method to reduce the influence of hard disk access time is called “data prefetch (DP)” method of the present invention. For most cases, computer program can predict which data block the program is going to use in the future. This statement is not true for small data accesses because logic operation may take different paths. However, hard disk operations are taking millions of bits at a time. Data accesses for large blocks are usually highly predictable. It is therefore possible to issue data prefetch instruction before we actually need to use the data. Operation of the DP method is shown in FIG. 5(b). When the system predicts that it is going to use a data block, the system issues a data prefetch instruction. Upon receiving of the prefetch instruction, the data storage system checks the main memory. If the desired block is not found in the main memory, a swapping procedure is started to obtain the target data. In the mean time, the computer and the rest of the system continue to execute other works in parallel. This prefetch should be early enough so that when the system actually needs the desired block, it is already in the main memory. In this way, the slowness of HD unit is hidden. Even if the system finishes all works before the prefetch operation is finished, the overall system performance is still improved. Such prefetch operation should have lower priority than normal hard disk operations. Therefore, no harm will be done to the overall system performance even if the prediction turn out to be wrong. Many methods can be used as the prediction mechanism to send out the data prefetch instruction. The simplest prediction is for the software programmer to place such prefetch instruction. A highly predictable situation is when the system is accessing a large block sequentially. For example, if the system already used data block 4, data block 5, and data block 6, it is strongly possible that we should pre-fetch data block 7. The prediction procedure to support such situation is shown in FIG. 5(c). A monitor records recently happened events. If a sequential access pattern is found, a prefetch command for the next block should be sent ahead of time. This method is called “sequential data prefetch (SDP)” of the present invention. The SDP method is an effective method to improve hard disk swapping space data overload problem. Another method is to make prediction based on recent operations; the procedure of this method is shown in FIG. 5(d). A monitor records the events of large data block access and place the events in a table. A new event displaces the oldest event in the table. The most recently happened events are compared to historical events in the table. If identical or similar patterns are found in the pass, we can predict what is going to happen in the future by assuming the same sequence is likely to be repeated. Prefetch instruction is sent based on this historical comparison. If multiple sequences are found in the history, we can either trust the most recent sequence or choose a few of those sequences. This method is called “predicted data prefetch (PDP)” method of the present invention. A data storage system of the present invention should use multiple prediction mechanisms.

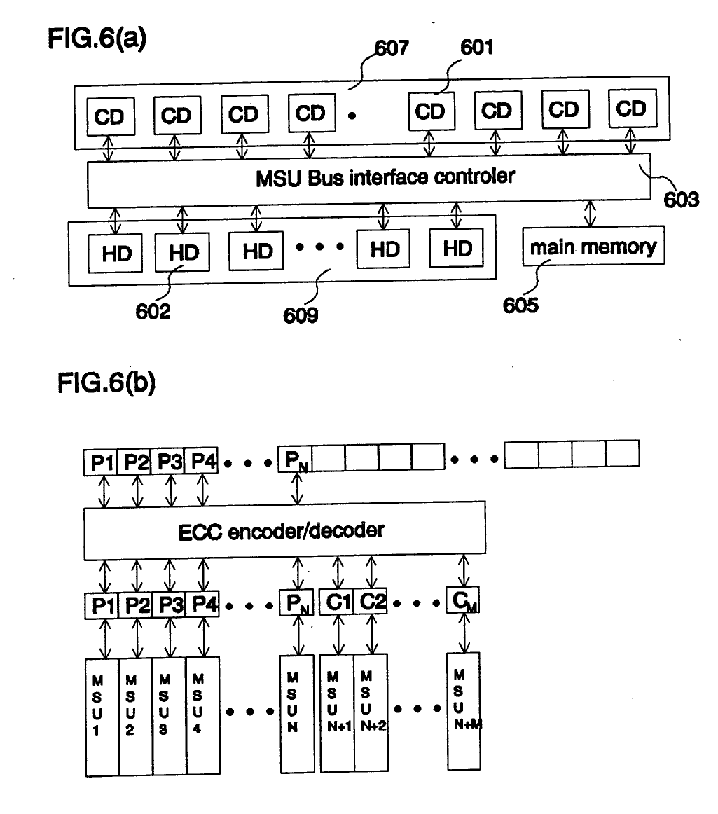

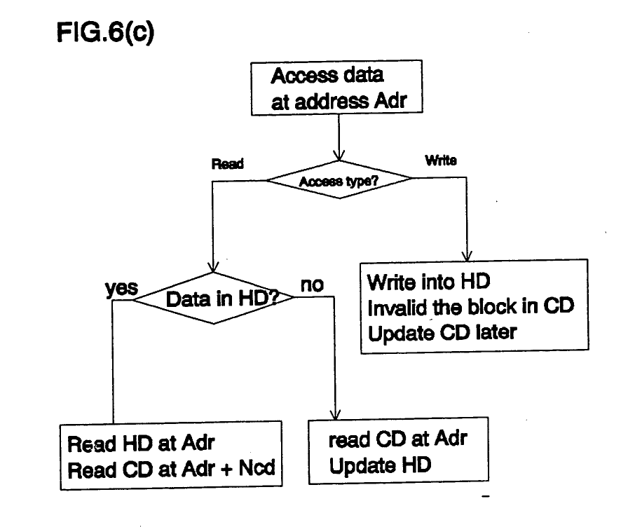

The operation principles for compact disk (CD) devices are very similar to those of hard disks. The above HD performance improvement methods (DPADR, DP, SDP, PDP) are all useful for CD. Another possible performance improvement method for CD is to combine CD and HD into a mass storage system as shown in the example in FIG. 6(a). CD is slower than HD in both access time and data transfer rate. It is therefore necessary to use parallel accesses and access time reducer methods to compensate for the slowness of CD. To improve data transfer rate, a plurality of CD units (601) and HD units (602) are connected in parallel to an MSU bus interface controller (603). Part or all of those buses also can be implemented in ADDTRA formats described previously. The DRAM main memory (605) is also connected to the controller (603). All the CD's are combined to form a pseudo CD device (607). It is desirable that all the CD's are synchronized—the headers of all disks always move to the same cylinder at the same section simultaneously, and that all of them has the same data transfer rates. However, that is not a necessary condition for the system to work. Similarly, it is also desirable that all the HD's are synchronized, but that is also not a necessary condition. All the HD's are combined to form a pseudo HD device (609). It is strongly desirable that the total data transfer rate of the pseudo CD (607) equals that of the pseudo HD (609), but that is not a necessary condition. The pseudo CD and the pseudo HD can be treated as separated devices, but it is desirable to use part of the HD storage capacity as an ATR or cache of the pseudo CD.

One important issue for data storage systems of the present invention is fault tolerance. The failure rate for IC devices are usually low. A data storage system of the present invention actually has simpler structure among IC devices, so that fault tolerance is not an issue there. Conventional error protection methods such as ECC protection are enough to assure excellent fault tolerance. The problem is among HD and CD devices. We are using many MSU's in parallel with complex control mechanisms. It is possible that part of the data may be lost due to noise problem. Sometimes one of the device may fail. Without excellent fault tolerance enhancement, the system in FIG. 6(a) would have much higher down time than conventional systems. It is therefore necessary to provide novel fault tolerance mechanism for MSU systems of the present invention.

For a prior art system with multiple mass storage units, the data are stored in MSU's as individual files. Different files are stored in different mass storage units. For example, file 1 stored in MSU 1, file 2 stored in MSU 2, . . . etc. A high cost computer called “file server” is used to control data flow in the network. The data in each file are usually cut into small packages for network data transfer. However, the packages belong to the same file always go to the same MSU. When one of the MSU fails, the system would fail if we want to access one of the files stored in the failed MSU.

The data storage systems of the present invention store data into mass storage units in different ways as shown in FIG. 6(b). The data in each file are cut into small packages (P1, P2, . . . P_{N}). The smallest unit for a data package is one binary bit, but the package can be any convenient length. For a write operation, N packages of data are sent to an ECC encoder/decoder that generates M error correction packages (C1, C2, . . . C_{N}) from the data packages. The data packages and error correction packages are written into MSU's in parallel. Package 1 is written into MSU1; Package 1 is written into MSU2; Package 3 is written into MSU3, . . . etc. For a read operation, the packages are read from multiple mass storage units in parallel, and decoded by the ECC encoder/decoder. The ECC circuits re-generate original data packages (P1, P2, . . . P_{N}), and combine those packages to generate the original file. ECC mechanisms will be able to recover correct data, even if one or multiple packages read from MSU's are wrong. Such ECC mechanisms are well-known in the art, there is no need to describe it in further details. The storage system shown in FIG. 6(b) is called “distributed data storage system (DDSS)” of the present invention. DDSS has the following advantages over the prior art systems. First of all, the data are accessed in parallel from a large number of MSU's so that the data transfer rates are N times higher than the prior art system. In addition, ECC mechanism assures the final data will be correct, even if some MSU's failed to execute data accesses correctly. In this system, it is possible to remove a few mass storage units while the system will still functions correctly. For the cases when the mass storage units have different speed, we also don't have to wait for the slowest device. As soon as most devices finished data transfer, the ECC decoder will be able to provide correct data.

Another performance enhancement is to use part of the pseudo HD (609) capacity as ATR for the pseudo CD (607). The operation procedures of this combined HD/CD system are shown in FIG. 6(c). For each new memory access at address Adr, the system check if the data is stored in the pseudo HD. For a read operation, if the data are found in the pseudo HD, the read operation starts in pseudo HD. In the mean time, the system check for the data starting from (Adr+Ncd) in the pseudo CD, where Ncd is the number of data the HD can read during the time when the CD is seeking for the target data location. Note that the seek time of the pseudo CD is a variable, so Ncd need to be determined based on estimated CD access time. If Ncd can not be determined accurately, a conservative number should be used. Once the pseudo CD is ready to read data, the pseudo HD stops its operation while the pseudo CD takes over. If the data is not found in the pseudo HD, read operation is executed by the pseudo CD starting from address Adr, and the data started from Adr to (Adr+Ncd) should be updated into the pseudo HD for future operations. If this is a data write operation, all the data are written into the pseudo HD. If the same data are found in the pseudo CD, the data block in the pseudo CD should be declared invalid. Write operations are only executed in HD's because CD's usually have poor performance for write operation. The newly written data can be placed into CD while the system is idle from other operations. Each individual CD's can be replaced or upgraded without shutting down the system if ECC is implemented.

The system describe in FIGS. 6(a-c) behaves as a pseudo MSU unit that has the speed of a parallel HD system with the capacity and cost of a CD system. As far as the main memory is concerned, the whole system behaves as a high performance hard disk with extremely large capacity.

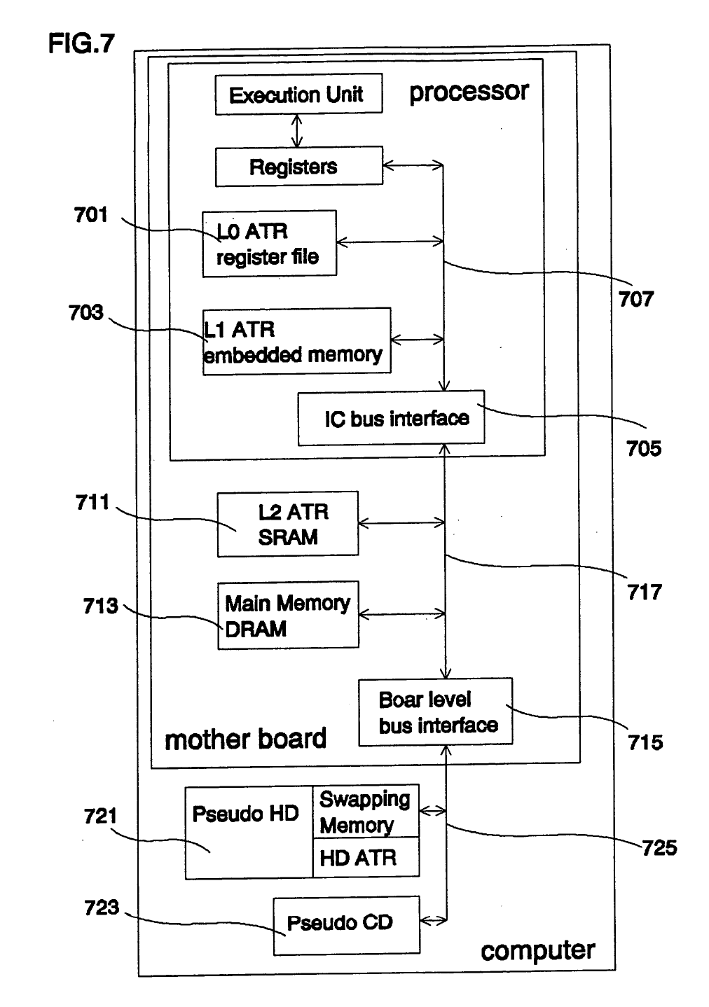

FIG. 7 shows an overview of a data storage system of the present invention. The execution unit operates on registers. Architecture of the present invention allow us to use a small register file (701) as the ATR of an embedded memory device (703). The register file (701) behaves as the level zero (L0) ATR, while the embedded memory (703) behaves as the L0 MSD. Combination of the L0 ATR/MSD is a storage device with the access time of register (701) and the capacity of the embedded memory (703). The registers, register file (701), and the embedded memory (703) communicates through an on-chip data bus (707). An IC bus interface (705) controls the data transfer between the on-chip data bus (707) and a board level data bus (717). Using methods described in FIGS. 4(a-e), those two buses (707, 717) are adjusted to have equal data transfer rate. The embedded memory (703) is then used as level 1 (L1) ATR to support an SRAM device (711). The SRAM device (711) is used as level 2 (L2) ATR to support the main memory (713). The L2 ATR and main memory communicates through the board level data bus (717). A board level bus interface controller (715) controls the communication between the board level data bus (717) and MSU data bus (725). Based on the architecture in FIGS. 6(a-c), a plurality of HD units are combined to form a high performance pseudo HD (721) unit, and a plurality of CD units are combined to form a pseudo CD (723) unit. Using methods described in FIGS. 4(a-e), the data transfer rates of those pseudo HD (721) and CD (723) units are adjusted to be the same at the board level data bus (717). The access time for the pseudo HD is improved by methods described in FIGS. 5(a-d). The access time for the pseudo CD is also improved by the same methods. In addition, part of the capacity in the pseudo HD (721) is used as the ATR of the pseudo CD (723) to reduce CD access time. For an user, the whole data storage system behaves as one memory device with the performance of a register file and the capacity of the combination of all HD's and CD's in the system. This system has unprecedented performance at relatively low price.

While specific embodiments of the invention have been illustrated and described herein, it is realized that other modifications and changes will occur to those skilled in the art. It is therefore to be understood that the appended claims are intended to cover all modifications and changes as fall within the true spirit and scope of the invention.

What is claimed is:

1. A data access system for accessing data stored in a first and a second memory devices wherein:
said first and second memory devices having a difference of latency ΔL constituting a time-duration by which said first memory device starts an initial data access earlier than in said second memory device; and
a data access means for simultaneously accessing data in said first and second memory devices and for stopping accessing data in said first memory device once a data access operation has begun in said second memory device whereby said first memory device storing data only accessed initially in a time duration corresponding substantially to said difference of latency ΔL.

2. The data access system of claim 1 wherein:
said first and second memory devices having substantially a same continuous data access rate after said initial data accesses in said first and second memory devices are completed.

3. The data access system of claim 1 wherein:
said second memory device comprising a dynamic random access memory (DRAM) and said first memory device comprising a static random access memory (SRAM).

4. The data access system of claim 3 wherein:
said DRAM comprising a plurality of rows and said SRAM storing first several data of a plurality of rows in said DRAM and said DRAM storing data of a plurality of entire rows in said DRAM.

5. A data memory system comprising:
a dynamic random access memory (DRAM) and a static random access memory (SRAM) wherein said DRAM comprising a plurality of rows and said SRAM storing first several data of a plurality of rows in said DRAM and said DRAM storing data of a plurality of entire rows in said DRAM.

6. The data memory system of claim 5 further comprising:
a data access means simultaneously accessing data in said DRAM and said SRAM for stopping a data access from said SRAM when an initial data access in said DRAM begins.

7. The data memory system of claim 5 further comprising:
a data access means for checking data access instructions for sending said data access instructions directly to said DRAM when a data access is for a data stored in a same row compared to a previous data access instruction.

8. The data memory system of claim 5 further comprising:
a data access means for checking data access instructions for sending said data access instructions to said SRAM and DRAM when a data access is for a data stored in a different row compared to a previous data access instruction.

9. The data memory system of claim 5 wherein:
said SRAM storing first several data of a plurality of rows in said DRAM for accessing data from said SRAM during a DRAM latency period; and
said DRAM storing data of a plurality of entire rows in said DRAM for accessing data from said DRAM immediately after said DRAM latency period.

10. A method for accessing data stored in a first and a second memory devices having a difference of latency ΔL constituting a time-duration by which said first memory device starts an initial data access earlier than in said second memory device, comprising:
simultaneously accessing data in said first and second memory devices and stopping accessing data in second first memory device once an initial data access in said second memory device begins.

11. The method of claim 10 further comprising:
configuring said first and second memory devices having substantially a same continuous data access rate after said initial data accesses in said first and second memory devices are completed

12. The method of claim 10 wherein:
said step of accessing data from said second memory device is a step of accessing data from a dynamic random access memory (DRAM) and said step of access data from said first memory is a step of accessing data from a static random access memory (SRAM).

13. The method of claim 12 wherein:
said step of access data from said DRAM comprising a step of dividing said DRAM into a plurality of rows and storing a plurality of entire rows of data in said DRAM and storing in said SRAM first several data of a plurality of rows as that stored into said DRAM.

14. A method of configuring data memory system comprising:
dividing a dynamic random access memory (DRAM) into a plurality of rows for storing data into a plurality of entire rows and storing first several data from a plurality of said rows of said DRAM in a static random access memory (SRAM).

15. The method of claim 14 further comprising:
simultaneously sending data access instructions to said DRAM and said SRAM for simultaneously accessing data in said SRAM and DRAM and stopping accessing data in said SRAM once an initial data access begins in said DRAM.

16. The method of claim 14 further comprising:
checking data access instructions for sending said data access instructions directly to said DRAM when a data access is for a data stored in a same row compared to a previous data access instruction.

17. The method of claim 14 further comprising:
checking data access instructions for sending said data access instructions to said SRAM and DRAM when a data access is for a data stored in a different row compared to a previous data access instruction and stopping accessing data in said SRAM once an initial data access begins in said DRAM.

18. The method of claim 14 wherein:
said step of storing in said SRAM first several data of a plurality of rows in said DRAM is a step of accessing data stored in said SRAM during a DRAM latency period; and
storing in said DRAM a plurality of entire rows in said DRAM for accessing data from said DRAM immediately after said DRAM latency period.
